(19) United States
(12) Patent Application Publication
(10) Pub. No.: US 2026/0212935 A1
(43) Pub. Date: Jul. 23, 2026

(54) MEMORY SYSTEM AND METHOD FOR OPTIMIZING READ BIAS

(71) Applicant: FADU Inc., Seoul (KR)

(72) Inventors: Hyeok JEONG, Gunpo-si (KR); Do Hee KIM, Seoul (KR)

(73) Assignee: FADU Inc., Seoul (KR)

(21) Appl. No.: 19/336,402

(22) Filed: Sep. 22, 2025

(30) Foreign Application Priority Data
Jan. 21, 2025 (KR) 10-2025-0008650

(51) Int. Cl. G11C 16/30; G11C 16/28

(52) U.S. Cl. CPC G11C 16/30; G11C 16/28

(57) ABSTRACT

The present disclosure relates to a memory system and a method for optimizing a read bias, and a read bias determination method according to an embodiment of the present disclosure, which is a method for determining a read bias of a nonvolatile memory device (110) including a plurality of memory cells (111), includes a step of modeling, by using a predetermined function having XY coordinate values, each of a plurality of threshold voltage distributions distributed in predetermined patterns according to an erase state and at least one program state of the memory cell (111) and arranged from left to right, and a step of determining an optimal read bias based on a correlation between two functions having modeled two most adjacent left and right threshold voltage distributions among the threshold voltage distributions.

### CROSS-REFERENCE TO RELATED APPLICATION(S)

This application claims the benefit under 35 USC 119(a) of Korean Patent Application No. 10-2025-0008650, filed with the Korean Intellectual Property Office on Jan. 21, 2025, the disclosure of which is incorporated herein by reference in its entirety.

### BACKGROUND

### 1. Technical Field

The present disclosure relates to a memory controller and a method for optimizing a read bias, and more particularly, to a technology of determining an optimal read bias in a nonvolatile memory device.

### 2. Related Art

Semiconductor memories are classified into volatile memories and nonvolatile memories according to an information storage mechanism. The volatile memory includes a DRAM, an SRAM, and the like, and has a high read/write speed but loses stored information when power is cut off. On the other hand, since the nonvolatile memory can retain stored information even when power is cut off, it is used for storing data to be retained regardless of the supply of power. Such a nonvolatile memory includes an EPROM, an EEPROM, an FRAM, a PRAM, an MRAM, a flash memory, and the like. In particular, the flash memory is widely used as audio and video data storage media in information devices such as computers, smartphones, digital cameras, voice recorders, and camcorders.

In particular, a NAND flash memory is widely used as a core element of a nonvolatile memory. However, due to inherent limitations in the number of data erases, the occurrence of bad blocks during production, and complexity such as erase operations to be necessarily performed before writing, the NAND flash memory is not used as a single component and forms a memory system combined with a memory controller.

A flash memory cell stores 1-bit data or multi-bit data. In the case of storing 1-bit data, a memory cell has two threshold voltage distributions corresponding to an erase state and a program state, respectively. A memory cell storing 2-bit data has four threshold voltage distributions corresponding to an erase state and three program states. A memory cell storing 3-bit data has eight threshold voltage distributions corresponding to an erase state and seven program states. A memory cell storing 4-bit data has 16 threshold voltage distributions corresponding to an erase state and 15 program states. The threshold voltage distribution refers to the number of memory cells corresponding to a threshold voltage, and the threshold voltage distribution of the memory cells is shifted due to various causes. Representative causes of the shift include a coupling effect, program disturbance due to programming of neighboring cells, retention, high-temperature stress, insulation degradation of an oxide film due to an increase in program/erase cycles, and the like.

When a read operation is performed with a previous read bias regardless of such a shift of the threshold voltage distribution, a bit error rate increases or an uncorrectable error correction code (UECC) occurs.

In this regard, a method is urgently required to determine an optimal read bias in correspondence to a shift of the threshold voltage distribution.

### SUMMARY

Various embodiments are directed to providing a memory system and a method that optimize a read bias by modeling a threshold voltage distribution of memory cells in a nonvolatile memory device by using a predetermined function and determining an optimal read bias based on a correlation between two adjacent modeled functions.

A read bias optimization method according to an embodiment of the present disclosure, which is a method for determining a read bias of a nonvolatile memory device including a plurality of memory cells, includes: (a) a step of modeling, by using a predetermined function having XY coordinate values, each of a plurality of threshold voltage distributions distributed in predetermined patterns according to an erase state and at least one program state of the memory cell and arranged from left to right; and (b) a step of determining an optimal read bias based on a correlation between two functions having modeled two most adjacent left and right threshold voltage distributions, respectively.

Furthermore, in the read bias optimization method according to an embodiment of the present disclosure, the function may include one or more selected from the group consisting of a parabolic function, a fraction function, and a linear function.

Furthermore, in the read bias optimization method according to an embodiment of the present disclosure, in the step (a), the threshold voltage distribution may be partitioned into left and right regions and each of the partitioned regions may be modeled.

Furthermore, in the read bias optimization method according to an embodiment of the present disclosure, the step (a) may include a step of selecting the function having predetermined coefficients; a step of determining the XY coordinate values of the function based on a plurality of reference read biases for reading data from the memory cells at different voltage levels and the number of memory cells counted based on the data read from the reference read biases; and a step of calculating the coefficients of the function based on the determined XY coordinate values.

Furthermore, in the read bias optimization method according to an embodiment of the present disclosure, one coordinate value xₙ of the XY coordinate values may indicate a first voltage level of any one of the plurality of reference read biases, and a coordinate value yₙ corresponding to the coordinate value xₙ of the XY coordinate values may be calculated using Equation 1 below,

$${y}_{n} = {C}_{n} - {C}_{n - 1} \qquad [ Equation 1 ]$$

in Equation 1 above, Cₙ is the number of memory cells up to the first voltage level, and Cₙ₋₁ is the number of memory cells up to a second voltage level lower than the first voltage level. Furthermore, in the read bias optimization method according to an embodiment of the present disclosure, in the step (b), a threshold voltage, which corresponds to an intersection point of the two functions having modeled the two most adjacent left and right threshold voltage distributions, may be determined as the optimal read bias.

Furthermore, in the read bias optimization method according to an embodiment of the present disclosure, in the step (b), the optimal read bias may be determined in a region of a threshold voltage corresponding to a region between a first X-intercept with a larger size among X-intercepts of a first function having modeled a left one of the two most adjacent left and right threshold voltage distributions and a second X-intercept with a smaller size among X-intercepts of a second function having modeled a right one of the two most adjacent left and right threshold voltage distributions.

A read bias optimization memory system according to an embodiment of the present disclosure includes: a nonvolatile memory device including a plurality of memory cells; and a memory controller that models, by using a predetermined function having XY coordinate values, each of a plurality of threshold voltage distributions distributed in predetermined patterns according to an erase state and at least one program state of the memory cell and arranged from left to right, and determines an optimal read bias based on a correlation between two functions having modeled two most adjacent left and right threshold voltage distributions, respectively.

Furthermore, in the read bias optimization memory system according to an embodiment of the present disclosure, the memory controller may include: a read command unit that provides the nonvolatile memory device with a plurality of read commands for reading data from the memory cell at different voltage levels; a bit counter that counts the number of memory cells based on the data read in response to the read commands; a coordinate value determination unit that determines the XY coordinate values of the function based on the voltage level and the number of memory cells; a function selection unit that selects the function based on the determined XY coordinate values of the function; and a read bias determination unit that determines the optimal read bias based on the selected function.

The features and advantages of the present disclosure will become more apparent from the following detailed description based on the accompanying drawings.

Prior to describing the present disclosure, the terms or words used in this specification and claims should not be construed as typical or dictionary definitions, but should be construed as meanings and concepts that coincide with the technical idea of the present disclosure, on the basis of a principle in which the inventor can appropriately define concepts of terms in order to explain his/her disclosure in a best way.

According to the present disclosure, an optimal read bias can be estimated even though there are changes in the location of a threshold voltage distribution, changes in a shape such as spreading or sharping, or changes in a distance ratio due to interference factors such as a retention time, an electric field effect due to data read, or temperature.

Furthermore, since the number of reads required for an operation is limited to a predetermined number depending on environments, it is advantages in terms of command response delay time.

In addition, since there are no parameters or results that need be defined in advance, no preliminary experiments are required for product application, thereby reducing time, material, and human resources.

### BRIEF DESCRIPTION OF THE DRAWINGS

FIG. 1 is a configuration diagram of a memory system.

FIG. 2 is a flowchart showing a program process of the memory system.

FIG. 3 is a threshold voltage distribution of a NAND flash memory cell (TLC).

FIG. 4 is a diagram that describes a process of determining an optimal read bias according to an embodiment of the present disclosure.

FIG. 5 is a diagram that describes a process of determining coordinate values of a function according to an embodiment of the present disclosure.

FIG. 6 is a diagram that describes a process of modeling a threshold voltage distribution by using a first parabolic function and determining an optimal read bias according to a first embodiment of the present disclosure.

FIG. 7 is a diagram that describes a process of bisecting and modeling a threshold voltage distribution by using a first parabolic function according to a second embodiment of the present disclosure.

FIG. 8 is a diagram that describes a process of bisecting and modeling a threshold voltage distribution by using a second parabolic function according to a third embodiment of the present disclosure.

FIG. 9 is a diagram that describes a process of bisecting and modeling a threshold voltage distribution by using a fraction function, and determining an optimal read bias according to a fourth embodiment of the present disclosure.

FIG. 10 is a diagram that describes a process of bisecting and modeling a threshold voltage distribution by using a linear function, and determining an optimal read bias according to a fifth embodiment of the present disclosure.

FIG. 11 is a configuration diagram of a memory system according to an embodiment of the present disclosure.

### DETAILED DESCRIPTION

The purpose, specific advantages, and new characteristics of the present disclosure will become more apparent from the following detailed description and preferred embodiments associated with the accompanying drawings. In this specification, in adding reference numerals to components of each drawing, it should be noted that only the same components are given the same reference numerals if possible even though they are illustrated in different drawings. Terms such as “first” or “second” are used to distinguish one component from another component, and the components are not limited by the terms. In the following description of the present disclosure, detailed descriptions of related known technologies that may unnecessarily obscure the gist of the present disclosure are omitted.

Hereinafter, preferred embodiments of the present disclosure are described in detail with reference to the accompanying drawings.

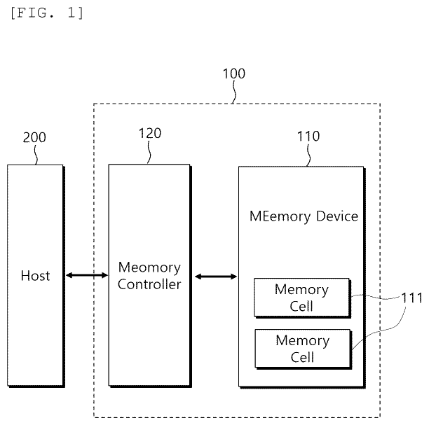

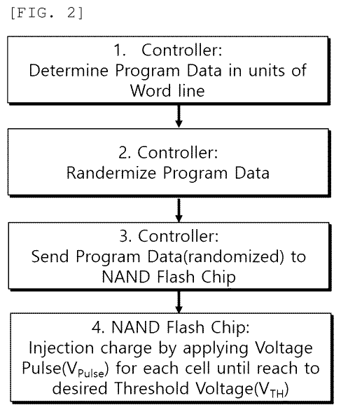

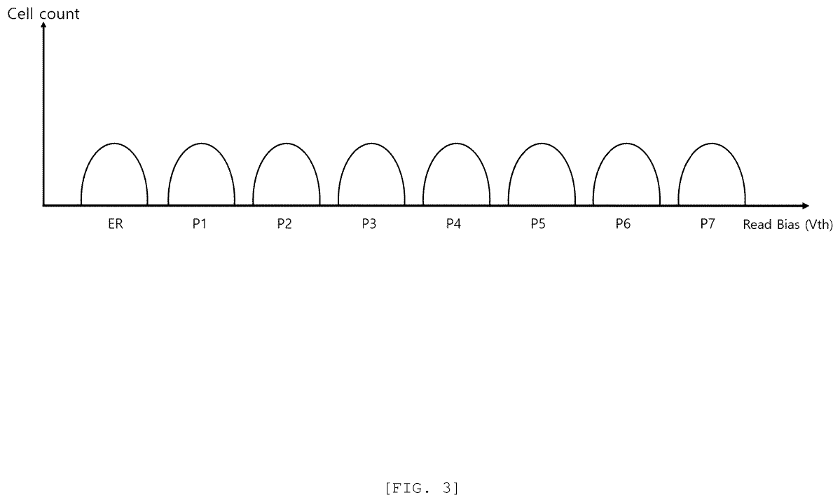

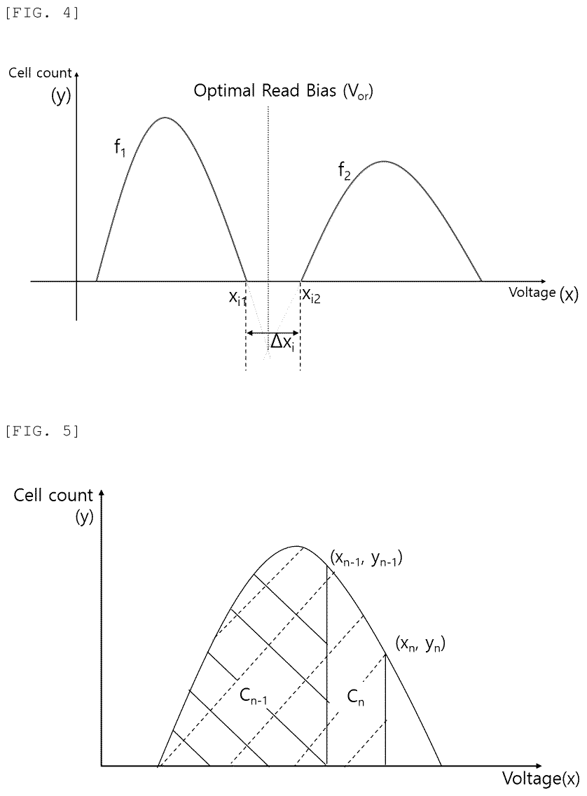

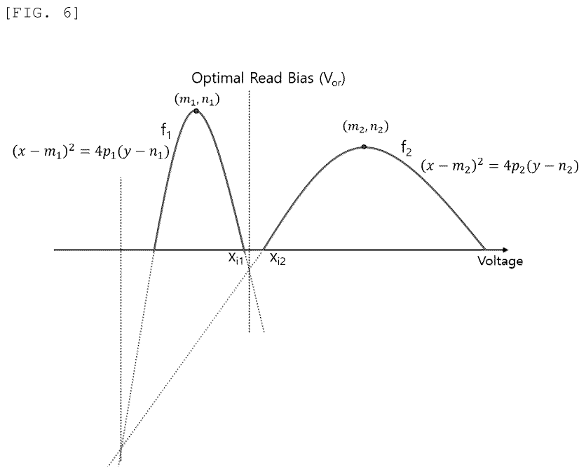

FIG. 1 is a configuration diagram of a memory system, FIG. 2 is a flowchart showing a program process of the memory system, FIG. 3 is a threshold voltage distribution of a NAND flash memory cell (TLC), FIG. 4 is a diagram that describes a process of determining an optimal read bias according to an embodiment of the present disclosure, and FIG. 5 is a diagram that describes a process of determining coordinate values of a function according to an embodiment of the present disclosure.

A read bias determination method of a nonvolatile memory device 110 according to an embodiment of the present disclosure is a method for determining a read bias of the nonvolatile memory device 110 including a plurality of memory cells 111, and includes a step of modeling, by using a predetermined function having XY coordinate values, each of a plurality of threshold voltage distributions distributed in predetermined patterns according to an erase state and at least one program state of the memory cell and arranged from left to right, and a step of determining an optimal read bias based on a correlation between two functions having modeled two most adjacent left and right threshold voltage distributions, respectively.

The present disclosure relates to a technology of optimizing a read bias of the memory cell 111 in a memory system 100. There occur changes in the location of a threshold voltage distribution, changes in a shape such as spreading or sharping, or changes in a distance ratio due to interference factors such as a retention time, an electric field effect due to data read, or temperature. Regardless of such changes in the threshold voltage distribution, when a read operation is performed with a read bias prior to the change, a bit error rate increases or an uncorrectable error correction code (UECC) occurs. As a solution for solving such a problem, the present disclosure has been devised.

Referring to FIG. 1, the memory system 100 includes a memory controller 120 and the nonvolatile memory device 110. Such a memory system 100 can be used in various computing systems such as smartphones, digital cameras, black boxes, and navigation devices. The memory controller 120 and the nonvolatile memory device 110 may be provided as a single chip, a package, a module, or the like, but are not necessarily limited thereto.

The memory controller 120 can control the nonvolatile memory device 110 in response to a request from a host 200. For example, in response to a data operation request received from the host 200, the memory controller 120 can control the memory device 110 so that data stored in the nonvolatile memory device 110 is read or data is written to the memory device 110. The memory controller 120 can control write, read, and erase operations of the memory device 110 by providing an address ADDR, a command CMD, a control signal, and the like to the memory device 110. Furthermore, data for the above operations can be transmitted and received between the memory controller 120 and the memory device 110.

The host 200 can transmit data operation requests and addresses to the memory controller 120, and exchange data with the memory controller 120. For example, the host 200 can exchange data with the memory controller 120 based on at least one of various interface protocols such as a universal serial bus (USB) protocol, a multi-media card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a mobile industry processor interface (MIPI) protocol, and a universal flash storage (UFS) protocol. Such a host 200 may include portable electronic devices such as smartphones and laptop computers, and electronic devices such as desktop computers, game machines, and televisions.

The nonvolatile memory device 110 may include at least one memory cell array. The memory cell array may include the plurality of memory cells 111 disposed in areas where a plurality of word lines and a plurality of bit lines intersect with each other. Each memory cell 111 may be a multi-level cell (MLC) that stores two or more bits of data. For example, each memory cell 111 may be a 2-bit MLC that stores two bits of data, a triple-level cell (TLC) that stores three bits of data, a quad-level cell (QLC) that stores four bits of data, or a multi-level cell that stores more than four bits of data. However, the present disclosure is not necessarily limited thereto. Some memory cells 111 may be single-level cells (SLCs) that store 1-bit data, while other memory cells 111 may be multi-level cells. The memory device 110 may include a NAND flash memory, a vertical NAND (VNAND) flash memory, a NOR flash memory, a resistive random access memory (RRAM), a phase-change random access memory (PRAM), a magnetoresistive random access memory (MRAM)), a ferroelectric random access memory (FRAM), a spin transfer torque random access memory (STT-RAM), and the like, and combinations thereof are also possible. The memory device 110 can perform operations such as data programming (writing), reading, and erasing in response to signals received from the memory controller 120. The memory cell array may include at least one memory block, and each memory block may include a plurality of pages. The NAND flash memory device 110 can perform an erase operation in units of blocks, and perform program (write) and read operations in units of pages corresponding to word lines. The page includes the plurality of memory cells 111 connected to one word line. In the nonvolatile memory device 110 including multi-level cells that store N (N is a natural number equal to or greater than 2) bits of data, N pages may be allocated to each word line. For example, in the case of a 2-bit MLC, two pages may be allocated to each word line, in the case of a TLC, three pages may be allocated to each word line, and in the case of a QLC, four pages may be allocated to each word line.

The memory cell 111 has a structure in which a source and a drain are disposed on a substrate and a channel region is formed between the source and the drain. A floating gate is formed above the channel region, and a tunneling insulating layer can be disposed between the channel region and the floating gate. A control gate is formed above the floating gate, and a blocking insulating layer can be disposed between the floating gate and the control gate. Voltages required for program, erase, and read operations on the memory cell 111 can be applied to the substrate, the source, the drain, and the control gate.

The state of the memory cell 111 can be distinguished by a threshold voltage Vₜₕ that is determined by the amount of electrons stored in the floating gate. The more electrons stored in the floating gate, the higher the threshold voltage of the memory cell 111. The memory cell 111 that stores N (N is a natural number equal to or greater than 2) bits of data has 2^{N} states corresponding to the distribution of threshold voltages. For example, a 2-bit MLC has an erase state where no electrons are stored and any one of the first, second, and third program states determined by the amount of introduced electrons. The threshold voltage is distinguished for each state, and increases from the erase state where no electrons are stored to the third program state where the amount of electrons is the largest.

With reference to FIGS. 2 and 3, the programming process of the memory system 100 is described. In response to a write request from the host 200, the memory controller 120 can determine program data in units of word lines being the smallest program unit of a memory. Subsequently, the memory controller 120 can randomize the program data in units of word lines. Specifically, the memory controller 120 processes data so that the memory cells 111 connected to one word line have the same percentage of program states. For example, in the case of a TLC where each of the memory cells 111 connected to one word line stores 3 bits of data, the memory controller 120 can randomize the data so that each of the memory cells 111 has an erase state (ER) and any one of first to seventh program states P1 to P7. Subsequently, the memory controller 120 sends the program data to a memory chip, and the memory chip applies a voltage pulse V_{Pulse} to inject electrons until each memory cell 111 is set to have a desired threshold voltage Vₜₕ. Accordingly, a plurality of threshold voltage distributions, in which threshold voltages are distributed in predetermined patterns according to an erase state and at least one program state of the memory cell 111, are arranged from left to right, i.e., in a direction in which the threshold voltage increases. For example, in the case of a TLC, the threshold voltage distribution of a programmed word line includes eight patterns corresponding to the erase state ER and the first to seventh program states P1 to P7 in an increasing order of threshold voltage. In the threshold voltage distribution of the memory cells 111, a horizontal axis indicates the threshold voltage, and a vertical axis indicates the number of memory cells 111.

In response to a read request from the host 200, the memory controller 120 controls the nonvolatile memory device 110 to sense and output data at a corresponding location by using a predetermined read bias. In order to ensure data reliability, the read bias needs to have a voltage level that can identify threshold voltages corresponding to the erase state and at least one program state of the memory cell 111.

However, the threshold voltage of the memory cell 111 may be changed due to various factors. In such a case, the level of the read bias needs to be adjusted to identify threshold voltage states. In this regard, the present disclosure provides a method for determining an optimal read bias having the lowest bit error rate.

Referring to FIG. 4, a method for determining a read bias of the nonvolatile memory device 110 according to an embodiment of the present disclosure is a method that is performed by the memory controller 120, and includes a function modeling step and an optimal read bias determination step.

The function modeling step is a process of modeling a plurality of threshold voltage distributions, which are distributed in predetermined patterns according to the state of the memory cell 111, by using a predetermined function. The plurality of threshold voltage distributions are arranged from left to right, i.e., along a direction in which the threshold voltage increases, according to the erase state and at least one program state of the memory cell 111. Such a shape of the plurality of threshold voltage distributions can be modeled using a predetermined function having XY coordinate values. For example, the modeling function may include one or more selected from the group consisting of a parabolic function, a fraction function, and a linear function. The threshold voltage distributions can be integrally modeled using one function, or each threshold voltage distribution can be partitioned into left and right regions and each of the partitioned regions can be modeled using one function.

In order to model the threshold voltage distribution, a function to be used for modeling can be selected. Since the function has predetermined coefficients, XY coordinate values of the function can be determined first, and the coefficients of the function can be calculated based on the determined XY coordinate values. The XY coordinate values can be determined based on a plurality of reference read biases and the number of memory cells 111. The plurality of reference read biases are read biases for reading data from the memory cells 111 at different voltage levels. The number of memory cells 111 can be counted based on the data read from the reference read biases.

Referring to FIG. 5, one coordinate value xₙ of the XY coordinate values indicates a first voltage level of any one of the plurality of reference read biases. A coordinate value yₙ corresponding to the coordinate value xₙ can be calculated using the following Equation 1.

$${y}_{n} = {C}_{n} - {C}_{n - 1} \qquad [ Equation 1 ]$$

In Equation 1 above, Cₙ is the number of memory cells 111 up to the first voltage level xₙ, and Cₙ₋₁ is the number of memory cells 111 up to a second voltage level xₙ₋₁ lower than the first voltage level.

When a read operation is performed by applying a predetermined reference read bias Vt to the nonvolatile memory device 110, memory cells 111 distributed at a potential equal to or lower than Vt are recognized as data “1” because a sufficient number of electron channels are formed between the source and the drain and current flows, and memory cells 111 distributed at a potential equal to or higher than Vt are recognized as data “0” because no current flows. Accordingly, by counting data “1”, the number of memory cells 111 distributed at a potential equal to or lower than Vt can be obtained. Such counting is called pattern counting or memory cell counting. Accordingly, data can be read based on the first voltage level xₙ, and the pattern counting (memory cell counting) can be performed to obtain Cₙ.

In the same manner, Cₙ₋₁ can be obtained through pattern counting performed on data read according to the second voltage level xₙ₋₁.

The n (n is a natural number equal to or greater than 1) X-coordinate values x₁ to xₙ applied to the function modeling can be determined in consideration of a preset reference X-coordinate value range. The reference X-coordinate value range is a range within which the n X-coordinate values are determined and can be set to a range of read bias levels with a low bit error rate. For example, a first reference X-coordinate value range for x₁ can be preset as a first reference voltage level V₁±a first effective range α₁, a second reference X-coordinate value range for x₂ can be preset as a second reference voltage level V₂±a second effective range α₂, a third reference X-coordinate value range for x₃ can be preset as a third reference voltage level V₃±a third effective range α₃, and the X-coordinate values can be determined within each of the reference X-coordinate value ranges. An interval between the reference X-coordinate value ranges can be defined as an optimal reference interval, one of the n X-coordinate values x₁ to xₙ can be determined, and then the remaining X-coordinate values can be determined by applying the optimal reference interval. For example, in the above example, an interval among the first to third reference voltage levels V₁ to V₃ can be defined as the optimal reference interval, one of the three X-coordinate values x₁ to x₃ can be determined, and then the remaining two X-coordinate values can be selected based on the optimal reference interval. However, the X-coordinate value does not necessarily have to be determined in consideration of the reference X-coordinate value range and may be determined in various ways. The number of XY coordinate values is n (n is a natural number equal to or greater than 1), and is equal to the number of coefficients in the modeling function. Accordingly, the modeling function can be defined by calculating the number of XY coordinate values equal to the number of coefficients in the modeling function, substituting the XY coordinate values into the function, and then obtaining the coefficients of the function by using a simultaneous equation.

As described above, each of the plurality of threshold voltage distributions is modeled using a function.

The optimal read bias determination step is a process of determining the optimal read bias by using the function that models the threshold voltage distribution. The optimal read bias is determined based on the correlation between two functions having modeled two most adjacent left and right threshold voltage distributions, respectively (see FIG. 4).

For example, a threshold voltage corresponding to an intersection point of two functions f₁ and f₂ having modeled two most adjacent left and right threshold voltage distributions, respectively, can be determined as the optimal read bias. The two most adjacent left and right threshold voltage distributions refer to, when a plurality of threshold voltage distributions are sequentially arranged corresponding to the erase state and at least one program state of the memory cell 111, an k^{th} (k is a natural number equal to or greater than 1) threshold voltage distribution and an k+1^{th} threshold voltage distribution among the plurality of threshold voltage distributions. For example, when the memory cell 111 is a TLC, a first threshold voltage distribution for the first program state can be modeled using a first function f₁, a second threshold voltage distribution for the second program state can be modeled as a second function f₂, and then an intersection point of the first function f₁ and the second function f₂ can be determined as the optimal read bias.

As another example, the optimal read bias can be determined in a region Δx₁ of the threshold voltage corresponding to a region between a first X-intercept xᵢ₁ with a larger size among X-intercepts of the first function f₁ having modeled the left one of the two most adjacent left and right threshold voltage distributions and a second X-intercept xᵢ₂ with a smaller size among X-intercepts of the second function f₂ having modeled the right one of the two most adjacent left and right threshold voltage distributions.

Hereinafter, the present disclosure is described in more detail by using embodiments of modeling threshold voltage distributions using a parabolic function, a fractional function, and a linear function and determining an optimal read bias.

### 1. First Embodiment: Parabolic Function Modeling

FIG. 6 is a diagram that describes a process of modeling a threshold voltage distribution by using a first parabolic function and determining an optimal read bias according to a first embodiment of the present disclosure.

Referring to FIG. 6, the threshold voltage distribution is modeled using the following parabolic function in the first embodiment of the present disclosure.

$${( x - m )}^{2} = 4 p ( y - n ) , p < 0$$

In order to define the parabolic function, coefficients m, n, and p need be obtained. Therefore, since three simultaneous equations are required, three XY coordinate values, that is, (x₁, y₁), (x₂, y₂), and (x₃, y₃) are determined. x₁, x₂, and x₃ are determined at the three aforementioned reference read bias levels, and y₁, y₂, and y₃ are determined based on the number of memory cells 111 up to respective reference read bias levels according to Equation 1 described above. When the three XY coordinate values determined in this way are substituted into the parabolic function, the following three equations can be obtained.

$${( {x}_{1} - m )}^{2} = 4 p ( {y}_{1} - n )$$

$${( {x}_{2} - m )}^{2} = 4 p ( {y}_{2} - n )$$

$${( {x}_{3} - m )}^{2} = 4 p ( {y}_{3} - n )$$

By using the three simultaneous equations above, m, n, and p can be obtained to define the parabolic function.

$$p = \frac{( {x}_{1}^{2} - {x}_{3}^{2} ) ( {x}_{1} - {x}_{2} ) - ( {x}_{1}^{2} - {x}_{2}^{2} ) ( {x}_{1} - {x}_{3} )}{4 ( ( {y}_{1} - {y}_{3} ) ( {x}_{1} - {x}_{2} ) - ( {y}_{1} - {y}_{2} ) ( {x}_{1} - {x}_{3} ) )}$$

$$m = \frac{( {y}_{1} - {y}_{3} ) ( {x}_{1}^{2} - {x}_{2}^{2} ) - ( {y}_{1} - {y}_{2} ) ( {x}_{1}^{2} - {x}_{3}^{2} )}{2 ( ( {y}_{1} - {y}_{3} ) ( {x}_{1} - {x}_{2} ) - ( {y}_{1} - {y}_{2} ) ( {x}_{1} - {x}_{3} ) )}$$

$$n = {y}_{1} - \frac{{( {x}_{1} - m )}^{2}}{4 p}$$

By the above method, each threshold voltage distribution is modeled using the parabolic function. The X-coordinates of an intersection point of two parabolic functions f₁((x−m₁)²=4p₁(y−n₁)) and f₂((x−m₂)²=4p₂ (y−n₂)), which have modeled two

$$Case {p}_{1} = {p}_{2} :$$

$$x = \frac{{m}_{1}^{2} - {m}_{2}^{2} + 4 p ( {n}_{1} - {n}_{2} )}{2 ( {m}_{1} - {m}_{2} )}$$

$$Case {p}_{1} \neq {p}_{2} :$$

$$x = \frac{\begin{matrix}( {m}_{1} {p}_{2} - {m}_{2} {p}_{1} ) \pm \\ \sqrt{{( {m}_{1} {p}_{2} - {m}_{2} {p}_{1} )}^{2} - ( {p}_{2} - {p}_{1} ) ( {p}_{2} {m}_{1}^{2} - {p}_{1} {m}_{2}^{2} + 4 {p}_{1} {p}_{2} {n}_{1} - 4 {p}_{1} {p}_{2} {n}_{2} )}\end{matrix}}{( {p}_{2} - {p}_{1} )}$$

adjacent threshold voltage distributions, respectively, are calculated as follow, and the intersection point is determined as the optimal read bias.

The intersection point is determined between the first X-intercept with a larger size among the X-intercepts of the first function f₁ on the left and the second X-intercept with a smaller size among the X-intercepts of the second function f₂ on the right.

### 2. Second Embodiment: Parabolic Function Modeling

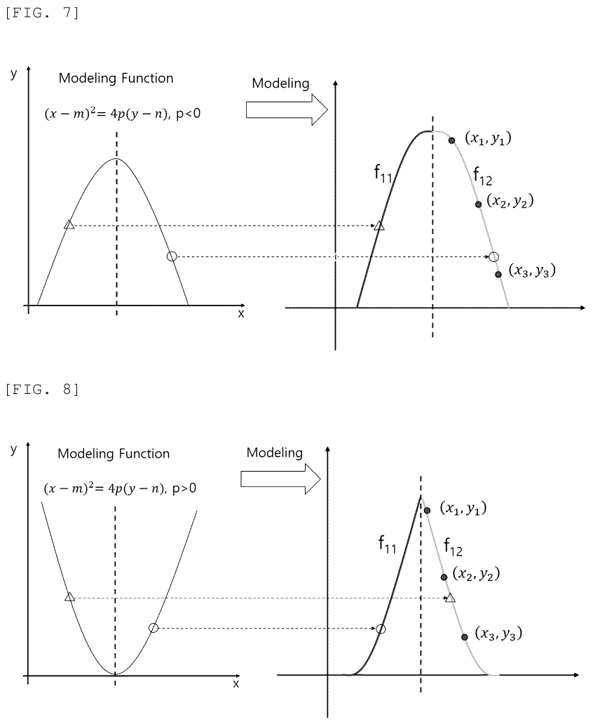

FIG. 7 is a diagram that describes a process of bisecting and modeling a threshold voltage distribution by using a first parabolic function according to a second embodiment of the present disclosure.

Referring to FIG. 7, in the second embodiment of the present disclosure, the threshold voltage distribution is bisected and the bisected regions are modeled using the following parabolic functions f₁₁ and f₁₂.

$${( x - m )}^{2} = 4 p ( y - n ) , p < 0$$

In order to define the parabolic function, coefficients m, n, and p need be obtained. Compared to the first embodiment, one threshold voltage distribution is bisected, and three XY coordinate values, that is, (x₁, y₁), (x₂, y₂), and (x₃, y₃) are determined for each bisected region. The XY coordinate values can be calculated in the same manner as described in the first embodiment.

Accordingly, one threshold voltage distribution can be modeled using two parabolic functions f₁₁ and f₁₂. Subsequently, as in the first embodiment, the optimal read bias can be determined as an intersection point of the functions having modeled two adjacent threshold voltage distributions.

### 3. Third Embodiment: Parabolic Function Modeling

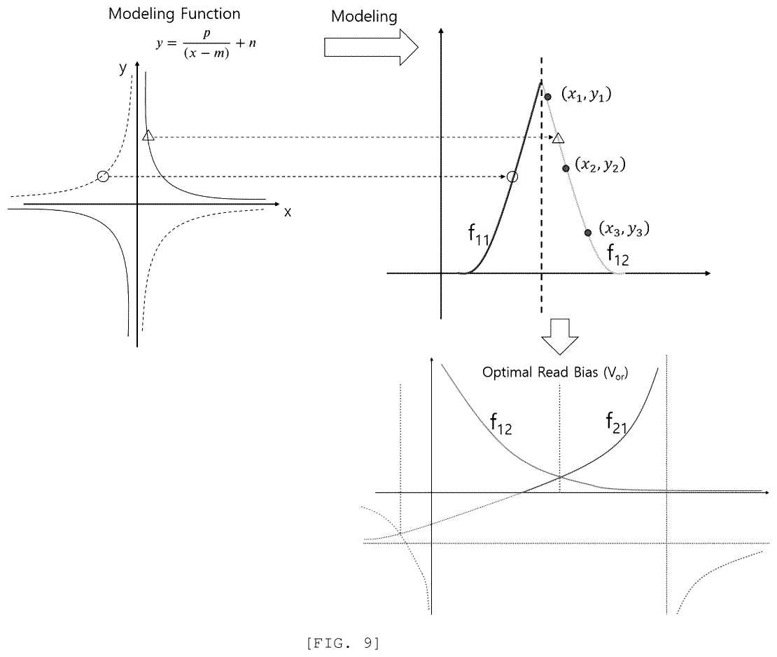

FIG. 8 is a diagram that describes a process of bisecting and modeling a threshold voltage distribution by using a second parabolic function according to a third embodiment of the present disclosure.

Referring to FIG. 8, in the third embodiment of the present disclosure, the threshold voltage distribution is bisected and the bisected regions are modeled using the following parabolic functions f₁₁ and f₁₂ as in the second embodiment.

$${( x - m )}^{2} = 4 p ( y - n ) , p > 0$$

In the parabolic function above, since p has a positive number, the parabolic function differs from the parabolic functions of the first and second embodiments in that the parabolic function has a downward convex shape.

By bisecting the threshold voltage distribution and modeling each bisected region by using the parabolic function above, the modeling can be performed in the same manner as in the second embodiment and the optimal read bias can be determined.

### 4. Fourth Embodiment: Fraction Function Modeling

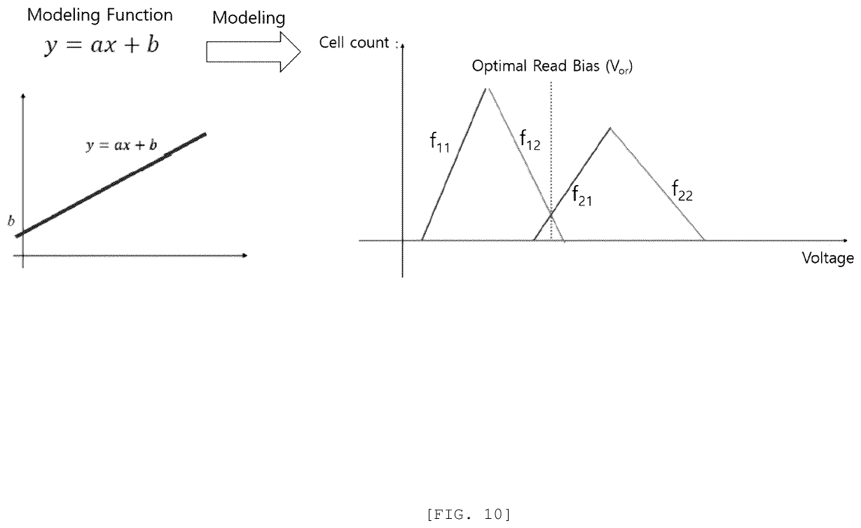

FIG. 9 is a diagram that describes a process of bisecting and modeling a threshold voltage distribution by using a fraction function, and determining an optimal read bias according to a fourth embodiment of the present disclosure.

Referring to FIG. 9, in the fourth embodiment of the present disclosure, the threshold voltage distribution is bisected and the bisected regions are modeled using the following fraction function as in the second and third embodiments.

$$y = \frac{p}{x - m} + n$$

In order to define the fraction function above, coefficients m, n, and p need be obtained. Therefore, since three simultaneous equations are required, three XY coordinate values, that is, (x₁, y₁), (x₂, y₂), and (x₃, y₃) are determined. x₁, x₂, and x₃ are determined at the three aforementioned reference read bias levels, and y₁, y₂, and y₃ are determined based on the number of memory cells 111 up to respective reference read bias levels according to Equation 1 described above. When the three XY coordinate values determined in this way are substituted into

$${y}_{1} = \frac{p}{{x}_{1} - m} + n$$

$${y}_{2} = \frac{p}{{x}_{2} - m} + n$$

$${y}_{3} = \frac{p}{{x}_{3} - m} + n$$

the fraction function, the following three equations can be obtained.

By using the three simultaneous equations above, m, n, and p can be obtained to define the fraction function.

The X-coordinates of an intersection point of two fraction functions f₁₂ and f₂₁, which have modeled two adjacent threshold voltage distributions, are calculated as follow, and the intersection point is determined as the optimal read bias.

$$n = \frac{( {y}_{1} - {y}_{2} ) ( {x}_{1} {y}_{1} - {x}_{3} {y}_{3} ) - ( {y}_{1} - {y}_{3} ) ( {x}_{1} {y}_{1} - {x}_{2} {y}_{2} )}{( {y}_{1} - {y}_{2} ) ( {x}_{1} - {x}_{3} ) - ( {y}_{1} - {y}_{3} ) ( {x}_{1} - {x}_{2} )}$$

$$m = \frac{{x}_{1} {y}_{1} - {x}_{2} {y}_{2} - ( {x}_{1} - {x}_{2} ) n}{{y}_{1} - {y}_{2}}$$

$$p = ( {x}_{1} - m ) ( {y}_{1} - n )$$

$${f}_{12 \to } y = \frac{{p}_{1}}{x - {m}_{1}} + {n}_{1} , {p}_{1} > 0$$

$${f}_{21 \to } y = \frac{{p}_{2}}{x - {m}_{2}} + {n}_{2} , {p}_{2} < 0$$

$$Case {n}_{1} = {n}_{2} :$$

$$x = - \frac{( {n}_{1} - {n}_{2} ) {m}_{1} {m}_{2} - {p}_{1} {m}_{2} + {p}_{2} {m}_{1}}{( {p}_{1} - {p}_{2} ) - ( {n}_{1} - {n}_{2} ) ( {m}_{1} + {m}_{2} )}$$

$$Case {n}_{1} \neq {n}_{2} :$$

$$x = \frac{\begin{matrix}- \{ ( {p}_{1} - {p}_{2} ) - ( {n}_{1} - {n}_{2} ) ( {m}_{1} + {m}_{2} ) \} \pm \\ \sqrt{\begin{matrix}{\{ ( {p}_{1} - {p}_{2} ) - ( {n}_{1} - {n}_{2} ) ( {m}_{1} + {m}_{2} ) \}}^{2} - \\ 4 ( {n}_{1} - {n}_{2} ) \{ ( {n}_{1} - {n}_{2} ) {m}_{1} {m}_{2} - {p}_{1} {m}_{2} + {p}_{2} {m}_{1} \}\end{matrix}}\end{matrix}}{2 ( {n}_{1} - {n}_{2} )}$$

### 5. Fifth Embodiment: Linear Function Modeling

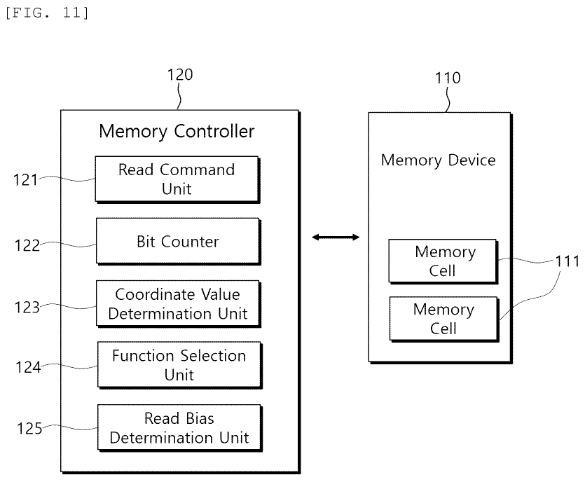

FIG. 10 is a diagram that describes a process of bisecting and modeling a threshold voltage distribution by using a linear function, and determining an optimal read bias according to a fifth embodiment of the present disclosure.

Referring to FIG. 10, in the fifth embodiment of the present disclosure, the threshold voltage distribution is bisected and the bisected regions are modeled using the following linear function.

$$y = ax + b$$

Since two XY coordinate values are required in order to define the linear function, two XY coordinate values are obtained from each bisected region by using the same method as in the first embodiment, and one threshold voltage distribution is modeled using two linear functions f₁₁ and f₁₂ or f₂₁ and f₂₂.

Subsequently, an intersection point of the linear functions f₁₂ and f₂₁, which have modeled two adjacent threshold voltage distributions, is determined as the optimal read bias.

Hereinafter, an embodiment of the memory controller 120 that is implemented to perform the read bias determination method of the nonvolatile memory device 110 described above is described. Overlapping content is omitted or briefly described.

FIG. 11 is a configuration diagram of the memory system 100 according to an embodiment of the present disclosure. As illustrated in FIG. 11, the memory system 100 according to an embodiment of the present disclosure includes a read command unit 121, a bit counter 122, a coordinate value determination unit 123, a function selection unit 124, and a read bias determination unit 125.

The read command unit 121 provides a plurality of read commands to the nonvolatile memory device 110. The plurality of read commands are provided by applying a plurality of reference read biases. The plurality of reference read biases have different voltage levels, so that data are read from the memory cells 111.

The bit counter 122 counts the number of memory cells 111 based on the data read in response to the read commands from the read command unit 121. That is, the bit counter 122 performs pattern counting or memory cell counting.

The coordinate value determination unit 123 determines XY coordinate values of a function that models a threshold voltage distribution, based on the voltage level of each of the plurality of reference read biases and the number of memory cells 111 counted by the bit counter 122.

The function selection unit 124 selects the function that models the threshold voltage distribution, based on the XY coordinate values determined by the coordinate value determination unit 123. The function may include one or more selected from the group consisting of a parabolic function, a fraction function, and a linear function. Since the modeling function has predetermined coefficients, the XY coordinate values are substituted and simultaneous equations are solved to finally define the function.

The read bias determination unit 125 determines an optimal read bias based on the function having modeled each threshold voltage distribution. The optimal read bias can be determined based on the correlation between two functions having modeled two most adjacent left and right threshold voltage distributions, respectively. For example, a threshold voltage corresponding to an intersection point of two functions having modeled two most adjacent left and right threshold voltage distributions, respectively, can be determined as the optimal read bias. As another example, the optimal read bias can be determined in a region of a threshold voltage corresponding to a region between a first X-intercept with a larger size among X-intercepts of a first function having modeled a left one of the two most adjacent left and right threshold voltage distributions and a second X-intercept with a smaller size among X-intercepts of a second function having modeled a right one of the two most adjacent left and right threshold voltage distributions.

The aforementioned read command unit 121, bit counter 122, coordinate value determination unit 123, function selection unit 124, and read bias determination unit 125 can each be implemented with hardware or software. That is, they can be implemented in the form of digital or analog circuits located inside the memory controller 120 or implemented with separate chips or modules and can be connected to the memory controller 120. They can also be implemented by storing software in an internal memory such as an SPAM or an external memory such as a floppy disk, a compact disk, or a USB, and executing the software. Furthermore, they can also be implemented in a user-programmable form or integrated into other internal modules (e.g., processors).

Although the present disclosure has been described in detail through specific embodiments, the embodiments are intended to illustratively describe the present disclosure in detail, the present disclosure is not limited thereto, and it is apparent that modifications or improvements thereof can be made within the technical scope of the invention by those skilled in the art.

All simple modifications and changes of the present disclosure fall within the scope of the present disclosure, and the specific scope of the present disclosure will be clarified by the appended claims.

What is claimed is:

1. A method for determining a read bias of a nonvolatile memory device including a plurality of memory cells, the method comprising:
(a) a step of modeling, by using a predetermined function having XY coordinate values, each of a plurality of threshold voltage distributions distributed in predetermined patterns according to an erase state and at least one program state of the memory cell and arranged from left to right; and
(b) a step of determining an optimal read bias based on a correlation between two functions having modeled two most adjacent left and right threshold voltage distributions, respectively.

2. The method of claim 1, wherein the function includes one or more selected from the group consisting of a parabolic function, a fraction function, and a linear function.

3. The method of claim 1, wherein, in the step (a), the threshold voltage distribution is partitioned into left and right regions and each of the partitioned regions is modeled.

4. The method of claim 1, wherein the step (a) comprises:
a step of selecting the function having predetermined coefficients;
a step of determining the XY coordinate values of the function based on a plurality of reference read biases for reading data from the memory cells at different voltage levels and the number of memory cells counted based on the data read from the reference read biases; and
a step of calculating the coefficients of the function based on the determined XY coordinate values.

5. The method of claim 4, wherein:
one coordinate value xₙ of the XY coordinate values indicates a first voltage level of any one of the plurality of reference read biases, and
a coordinate value yₙ corresponding to the coordinate value xₙ of the XY coordinate values is calculated using Equation 1 below,
$${y}_{n} = {C}_{n} - {C}_{n - 1} \qquad [ Equation 1 ]$$
in Equation 1 above, Cₙ is the number of memory cells up to the first voltage level, and Cₙ₋₁ is the number of memory cells up to a second voltage level lower than the first voltage level.

6. The method of claim 1, wherein, in the step (b), a threshold voltage, which corresponds to an intersection point of the two functions having modeled the two most adjacent left and right threshold voltage distributions, is determined as the optimal read bias.

7. The method of claim 1, wherein, in the step (b), the optimal read bias is determined in a region of a threshold voltage corresponding to a region between a first X-intercept with a larger size among X-intercepts of a first function having modeled a left one of the two most adjacent left and right threshold voltage distributions and a second X-intercept with a smaller size among X-intercepts of a second function having modeled a right one of the two most adjacent left and right threshold voltage distributions.

8. A memory system comprising:
a nonvolatile memory device including a plurality of memory cells; and
a memory controller that models, by using a predetermined function having XY coordinate values, each of a plurality of threshold voltage distributions distributed in predetermined patterns according to an erase state and at least one program state of the memory cell and arranged from left to right, and determines an optimal read bias based on a correlation between two functions having modeled two most adjacent left and right threshold voltage distributions, respectively.

9. The memory system of claim 8, wherein the memory controller comprises:
a read command unit that provides the nonvolatile memory device with a plurality of read commands for reading data from the memory cell at different voltage levels;
a bit counter that counts the number of memory cells based on the data read in response to the read commands;
a coordinate value determination unit that determines the XY coordinate values of the function based on the voltage level and the number of memory cells;
a function selection unit that selects the function based on the determined XY coordinate values of the function; and
a read bias determination unit that determines the optimal read bias based on the selected function.
